(19) United States
(12) Patent Application Publication
(10) Pub. No.: US 2015/0218425 A1
(43) Pub. Date: Aug. 6, 2015

(54) STRETCH RELEASE CONDUCTIVE ADHESIVE

(71) Applicant: Apple Inc., Cupertino, CA (US)

(72) Inventors: Julian MALINSKI, Miami Beach, FL (US); Richard Hung Minh DINH, Saratoga, CA (US); Daniel W. JARVIS, Sunnyvale, CA (US)

(21) Appl. No.: 14/502,913

(22) Filed: Sep. 30, 2014

Related U.S. Application Data
(63) Continuation of application No. PCT/US14/58263, filed on Sep. 30, 2014.
(60) Provisional application No. 61/936,296, filed on Feb. 5, 2014.
(60) Provisional application No. 61/936,811, filed on Feb. 6, 2014.
(60) Provisional application No. 61/937,409, filed on Feb. 7, 2014.

(51) Int. Cl. C09J 9/02; B32B 37/26; B32B 37/12; H05K 1/02; B32B 37/18

(52) U.S. Cl. CPC C09J 9/02; H05K 1/0283; B32B 37/18; B32B 37/1284; B32B 37/26; H05K 2201/2063; H05K 2201/2072; B32B 2037/1246; B32B 2037/268; B32B 2307/748; B32B 2457/00

(57) ABSTRACT

This application relates to adhesives for use in electronic devices. Specifically, the embodiments discussed herein set forth stretch release conductive adhesives for adhering an electrical component to the surface of a housing of a computing device while also allowing current to flow through the electrical component. A stretch release conductive adhesive can include a graspable portion for providing a means to stretch and remove the stretch release conductive adhesive from an electronic device.

### CROSS-REFERENCE TO RELATED APPLICATIONS

The present application claims the benefit of U.S. Provisional Application No. 61/936,296, of the same title, filed Feb. 5, 2014, U.S. Provisional Application No. 61/936,811, of the same title, filed Feb. 6, 2014, and U.S. Provisional Application No. 61/937,409, of the same title, filed Feb. 7, 2014, the contents of which are incorporated herein by reference in their entirety for all purposes.

This application is a continuation of International Application PCT/US14/58263, with an international filing date of Sep. 30, 2014, entitled “STRETCH RELEASE CONDUCTIVE ADHESIVE,” the disclosure of which is incorporated herein by reference in its entirety.

### FIELD

The described embodiments relate generally to methods for mounting components to and removing components from a computing device. More particularly, the embodiments set forth various removal systems that utilize conductive adhesive material that allows non-destructive removal of the components.

### BACKGROUND

A portable computing device can include many components that provide operational functionality for users of the device. For example, a typical portable computing device can include a processor, multiple connectors, an antenna, flexible circuits, one or more fans, speakers, batteries, and the like. Notably, overall sizes of portable computing devices are continually shrinking in response to a demand for smaller, lighter devices. To meet this demand, internal components of the portable computing device are being made smaller and are being mounted in more consolidated arrangements.

One approach for mounting a component within a portable computing device includes the use of double-sided adhesive tape. However, this method can make removing the component difficult and time consuming and can leave behind adhesive residue that must be cleaned before reinstalling a replacement component. Further, this approach can result in damaging the component during the removal process, which can be costly and inefficient.

### SUMMARY

This paper describes various embodiments that relate to methods and systems for mounting and removing components within a computing device. In particular, disclosed herein are various component mounting and removal apparatuses that are conductive and enable a component (e.g., a flexible circuit) to be securely installed into a computing device. Moreover, these component mounting and removal apparatuses enable the component to be easily removed from the computing device when servicing or replacement is required.

According to one embodiment, a stretch release conductive adhesive used for extracting a component that is secured to a surface of a housing is disclosed. The stretch release conductive adhesive can include a conductive adhesive body that adheres the component to the housing surface and allows a current to flow from the component into the surface of the housing through the stretch release conductive adhesive. A portion of the conductive adhesive body can extend out from between the component and the housing to provide a graspable portion. When a removing force is applied to the graspable portion, the graspable portion independently transfers the removing force to at least the conductive adhesive body disposed between the component and the housing surface.

According to another embodiment, a stretch release conductive adhesive for extracting a component or flexible circuit from a housing is disclosed. The stretch release conductive adhesive is conductive and includes a compressible securing portion designed to secure the component to an interior surface of the housing at a securing thickness. The stretch release conductive adhesive also includes an extracting portion coupled to the compressible securing portion at a junction. The extracting portion is arranged to receive and transfer an extracting force to the compressible securing portion by way of the junction. In turn, the extracting force reduces the thickness of the compressible securing portion at a detaching region. The detaching region is located a distance away from the junction to cause detachment of the component.

According to another embodiment, a method of extracting a component or flexible circuit from a housing using a stretch release conductive adhesive is disclosed. The stretch release conductive adhesive is conductive and includes a compressible securing portion coupled to an extracting portion at a junction. The method includes applying an extracting force to the extracting portion. The method also includes transferring the extracting force to the compressible securing portion by way of the junction. The extracting force causes a reduction in thickness of the compressible securing portion at a detaching region. The thickness of the compressible securing portion in turn shrinks from a securing thickness to a reduced thickness. The component is secured to an interior surface of the housing when the compressible securing portion is at the securing thickness. Conversely, the component is detached from the interior surface of the housing when the compressible securing portion is at the reduced thickness.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The disclosure will be readily understood by the following detailed description in conjunction with the accompanying drawings, wherein like reference numerals designate like structural elements.

FIG. 1 illustrates a view of a stretch release conductive adhesive in a securing state, according to one embodiment.

FIG. 2 illustrates a view of a stretch release conductive adhesive in a stretched state, according to one embodiment.

FIG. 3 illustrates a view of a conductive pathway created by a stretch release conductive adhesive between a flexible circuit and housing, according to one embodiment.

FIG. 4 illustrates a view of a stretch release conductive adhesive having one extracting portion securing a flexible circuit to a housing, according to one embodiment.

FIG. 5 illustrates a view of a stretch release conductive adhesive having multiple extracting portions securing a flexible circuit to a housing, according to one embodiment.

FIG. 6 illustrates a method for securing a flexible circuit to a housing using stretch release conductive adhesive, according to one embodiment.

FIG. 7 illustrates a method for removing a flexible circuit from a housing using stretch release conductive adhesive, according to one embodiment.

### DETAILED DESCRIPTION

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

As the size and weight of computing devices and other electronic devices decreases, retention mechanisms for components included in these devices become smaller as well. Adhesive tape can be particularly effective at retaining components within a device while occupying a minimal amount of space. Several types of adhesive tape have been designed to address this problem. In particular, a pressure sensitive adhesive can be applied to one or both sides of a highly extensible backing The backing can be formed from a highly extensible polymeric material with a high tensile strength and a lengthwise elongation at break in excess of 700%. When a force is applied to stretch the backing in a direction substantially parallel to the surface of the tape, the backing deforms causing the adhesive to elongate and detach from the surface. These are commonly referred to as stretch release adhesives. Examples of adhesive tapes that meet these requirements are Command™ adhesives produced by 3M™ and Powerstrip™ adhesives produced by Tesa™. By combining the features of conductive adhesive and stretch release adhesives the deficiencies of many commonly used adhesives in computing devices are resolved.

In some applications, adhesives must be conductive in order to allow electrons to travel through the adhesive. For example, components such as flexible circuits within a computing device are adhered to the interior surface or housing of the computing device in order to provide grounding for the flexible circuits. During repair or rework of the computing device, flexible circuits are often removed. Typically, removal causes damage to the flexible circuits because the conductive adhesives attaching the flexible circuits were not designed for removal. Therefore, by removably attaching flexible circuits to the housing, less time is spent cleaning adhesive residue and less flexible circuits are damaged during repair and rework.

As set forth above, one common technique for securing a component (e.g., a flexible circuit) within a computing device involves using a conductive adhesive. When the component needs to be removed from the computing device, service technicians are required to pry the component away from the housing of the computing device, which can damage the component and/or housing. One technique that can be used to help mitigate this problem is by securing a stretch release conductive adhesive layer between the component and the housing. Accordingly, one embodiment sets forth a stretch release conductive adhesive used for extracting a component (e.g., a flexible circuit) secured to an interior surface or housing of a computing device, such as a housing of the computing device. The stretch release conductive adhesive can include a conductive compressible securing portion and an extracting portion coupled at a junction. The conductive compressible securing portion is placed between the component and the housing, and is designed to facilitate removal of the stretch release conductive adhesive by providing a means (i.e., by pull tab or extracting portion) by which to grip the stretch release conductive adhesive and pull it without tearing it through the creation of stress concentrations.

In some embodiments, the extracting portion can be made of the same or different material as the conductive compressible securing portion. In one embodiment, the extracting portion can be made of a plastic material that is less compressible than the conductive compressible securing portion. In some embodiments, the extracting portion includes an inner portion that is made of the same material as the conductive compressible securing portion and an outer sheath that covers the conductive compressible securing portion. The extracting portion can have a thickness that is thinner or thicker than compressible securing portion. In some embodiments, portions of the extracting portion can have features such as grooves or projections that can facilitate a grasping of the extracting portion. The grooves can range from sharp angles to smooth bumps across the extracting portion.

The stretch release conductive adhesive can be made conductive by any suitable means, such as incorporating any conductive elements, particles, or compounds into the adhesive material. For example, common conductive materials such as silver, copper, gold, aluminum, calcium, tungsten, zinc, nickel, lithium, iron, etc., can be incorporated into the stretch release conductive adhesive to make it conductive. Moreover, nanoparticles such as gold, zinc, silver, carbon, etc., can also be incorporated into the stretch release conductive adhesive to make it conductive.

The stretch release conductive adhesive can be used in a mobile device, media player, or any other computing device in which internal components can be housed. Furthermore, a variety of internal components—including batteries, fans, speakers, circuit boards, cables, wires, and other electronic components—can be secured within the housing by way of the stretch release conductive adhesive. The stretch release conductive adhesive can be applied such that a number of components are attached at a single junction formed of stretch release conductive adhesive. For example, one or multiple layers of stretch release conductive adhesive can be used to ground multiple flexible circuits to a surface associated with a housing of a portable electronic device and the like.

In some embodiments, the stretch release conductive adhesive can include a conductive compressible securing portion and an extracting portion coupled at a junction. When a conductive compressible securing portion is at a securing thickness between a flexible circuit and a housing, the conductive compressible securing portion can secure the flexible circuit to the housing while also providing a conductive pathway between the housing and the flexible circuit. When the conductive compressible securing portion is at a reduced thickness, the compressible securing portion can detach the flexible circuit from the housing without damaging the flexible circuit. Thus, when an extracting force F is transferred to a detaching region between the flexible circuit and the housing, a compressible securing region can begin to detach the flexible circuit from the housing. As extracting force F continues to be applied to the extracting portion, the thickness of the conductive compressible securing portion is reduced until substantially the entire conductive compressible securing portion has a sufficiently reduced thickness. The thickness of the conductive compressible securing portion is sufficient when the flexible circuit is no longer adhered to the housing and the flexible circuit can be easily removed from the housing. In this way, the stretch release conductive adhesive can be used to attach, extract, and provide a conductive pathway between the flexible circuit and the housing or surface for which the stretch release conductive adhesive is removably attached. In some embodiments, the stretch release conductive adhesive can be pulled with extraction force F at an angle that is substantially parallel, non-parallel, or at a non-zero angle with relation to the flexible circuit, component, or surface.

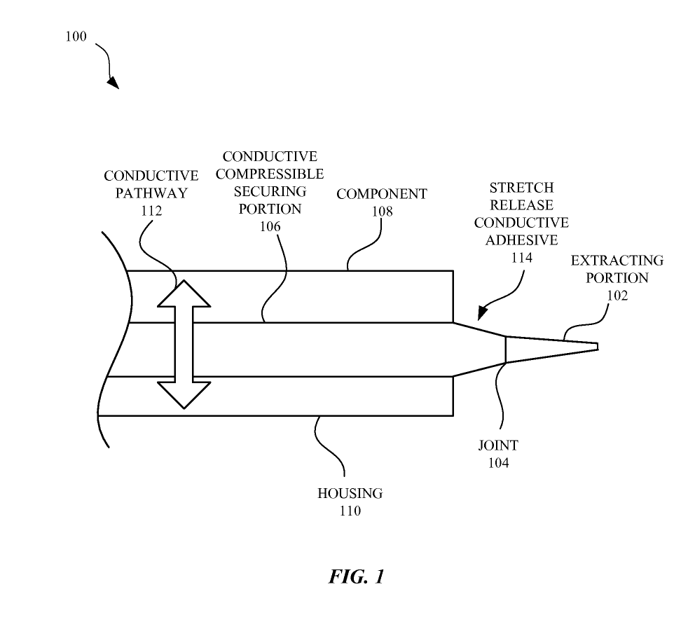

These and other embodiments are discussed below with reference to FIGS. 1-7; however, those skilled in the art will readily appreciate that the detailed description given herein with respect to these figures is for explanatory purposes only and should not be construed as limiting.

FIG. 1 illustrates a perspective view 100 of a stretch release conductive adhesive 114 in a securing state according to one embodiment of the invention. In particular, FIG. 1 illustrates a view of the stretch release conductive adhesive 114 securing a component 108 to a surface of a housing 110. As shown, the stretch release conductive adhesive 114 includes a conductive compressible securing portion 106 that provides a conductive pathway 112 from the component 108 to the housing 110. The stretch release conductive adhesive 114 can further include an extracting portion 102 that is coupled to the conductive compressible securing portion 106 by a joint 104. The joint 104 is not essential in some embodiments.

The extracting portion 102 can take many forms, for example, extracting portion 102 can take the form of a tab, a ring, a string, etc. or any form suitable for grasping and pulling. This arrangement allows for a component such as a flexible circuit to be removably attached to the housing of a computing device while also grounding the flexible circuit to the housing. The extracting portion 102 can be positioned relative to the compressible securing portion 106 in any number of configurations, for example a zero, non-zero, or negative angle in relation to the compressible securing portion 106. In some embodiments, there can be multiple extracting portions 102 that provide multiple gripping areas facilitating removal of stretch release conductive adhesive 114. In some embodiments, the joint 104 is adjacent to a low friction material or acute edge that can facilitate movement of the stretch release conductive adhesive 114 along the edge of or away from the component 108.

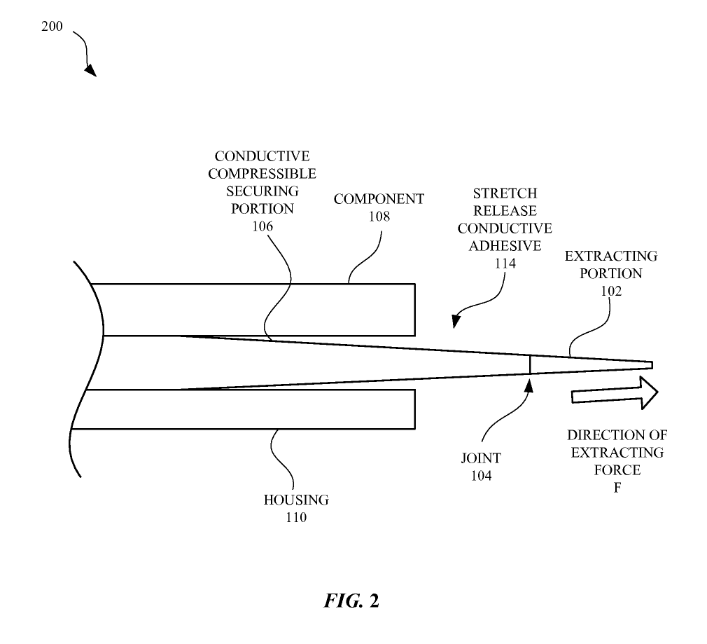

FIG. 2 illustrates a perspective view 200 of a stretch release conductive adhesive 114 in a stretched state according to one embodiment of the invention. In particular, FIG. 2 illustrates a view of the stretch release conductive adhesive 114 being extracted from between component 108 and housing 110 by an extracting force F. As shown, the stretch release conductive adhesive 114 is displaced from between the component 108 and the housing 110 by an extracting force F applied to the extracting portion 102. The extracting force F is transferred to the conductive compressible securing portion 106 by way of the joint 104 to reduce the thickness of the conductive compressible securing portion 106 between the component 108 and the housing 110 from a securing thickness to a reduced thickness. The region from which the stretch release conductive adhesive 114 detaches can be located between the component 108 and the housing 110. This arrangement allows for a flexible circuit to be removed from the housing 110 without damaging the flexible circuit (i.e. the component 108) or leaving a residue.

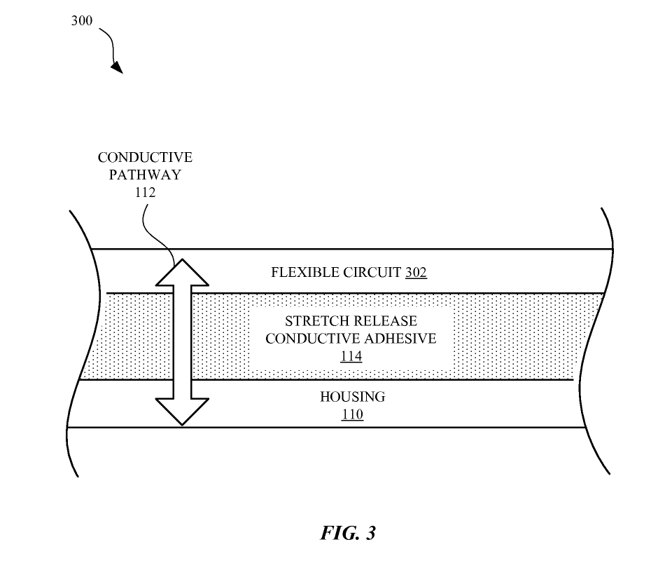

FIG. 3 illustrates a perspective view 300 of a conductive pathway 112 created by a stretch release conductive adhesive 114 between a flexible circuit 302 and a housing 110, according to one embodiment. In particular, FIG. 3 illustrates the conductive pathway 112 created by the conductive material included in the stretch release conductive adhesive 114. As discussed herein, any variety of conductive materials can be included in the stretch release conductive adhesive 114 in order to create the conductive pathway 112 shown in FIG. 3. Upon rework or repair of computing device in which the housing 110 and flexible circuit 302 are retained, the stretch release conductive adhesive 114 is easily removed without damaging the flexible circuit 302. The flexible circuit 302 can then by reused by technicians operation on the computing device, thereby saving material costs and speeding up the removal process.

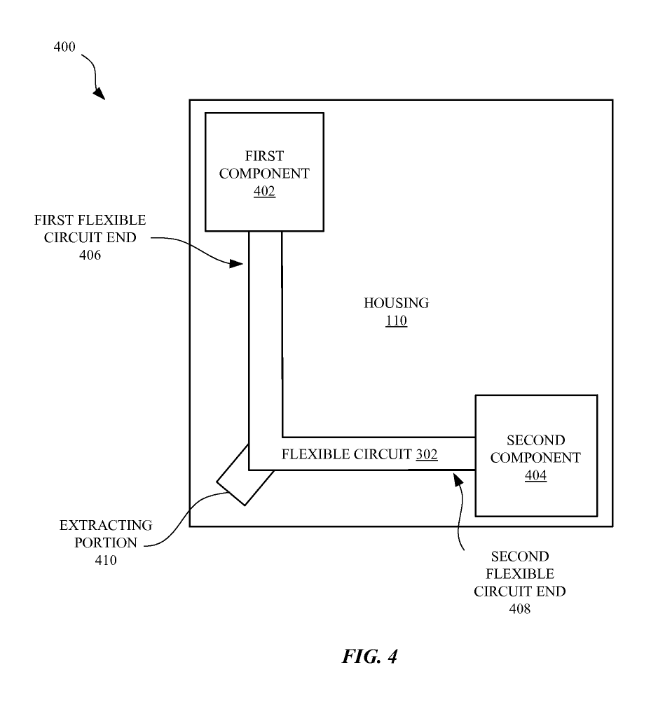

FIG. 4 illustrates a perspective view 400 of a stretch release conductive adhesive having an extracting portion 410 and securing a flexible circuit 302 to a housing 110, according to one embodiment. In particular, FIG. 4 illustrates a first component 402 and a second component 404 being connected by a flexible circuit 302. The extracting portion 410 is configured to be easily found and gripped by a technician or machine. The first component 402 and second component 404 are connected to a housing 110, and the flexible circuit 302 is grounded to the housing 110 by the stretch release conductive adhesive. Once disconnected from first component 402 and second component 404, the flexible circuit 302 ends, first flexible circuit end 406 and second flexible circuit end 408, are easily removed from the housing 110 by pulling on the extracting portion 410. For example, during rework of the housing 110, a technician will simply disconnect the flexible circuit 302 from the first components 402 and the second component 404, then pull on the extracting portion 410 until the first flexible circuit end 406 and second flexible circuit end 408 are released from the housing 110. The technician is then free to use the flexible circuit 302 again.

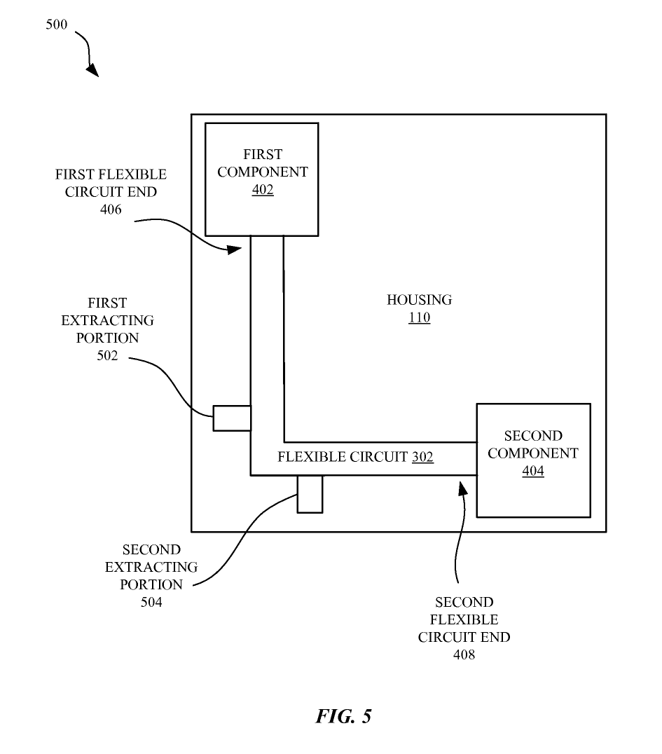

FIG. 5 illustrates a perspective view 500 of a stretch release conductive adhesive having multiple extracting portions and securing a flexible circuit to a housing, according to one embodiment. In particular, FIG. 5 illustrates the first component 402 and the second component 404 connected by a flexible circuit 302, and the flexible circuit 302 grounded to a housing 110 by the stretch release conductive adhesive. The stretch release conductive adhesive is adhered between the flexible circuit 302 and the housing 110, providing a conductive pathway from the flexible circuit 302, through the stretch release conductive adhesive, to the housing 110. The first extracting portion 502 and second extracting portion 504 are attached to the stretch release conductive adhesive. Once the flexible circuit 302 is disconnected from the first component 402 and the second component 404, a technician or machine can pull on either the first extracting portion 502 or the second extracting portion 504, to remove the first flexible circuit end 406 and/or the second flexible circuit end 408, respectfully, from the housing 110. By pulling on both the first extracting portion 502 and the second extracting portion 504, the flexible circuit 302 will be completely released. For example, during rework of the housing 110, a technician or machine will disconnect the flexible circuit 302 from the first component 402 and the second component 404, then simply pull on the both the first extracting portion 502 and the second extracting portion 504 until both the first flexible circuit end 406 and the second flexible circuit end 408, respectfully, are released from the housing 110. The technician is then free to use the flexible circuit 302 again.

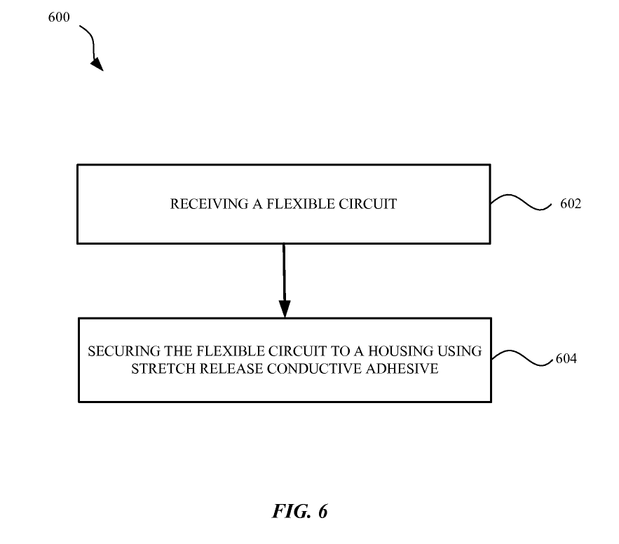

FIG. 6 illustrates a method 600 for securing a flexible circuit to a substrate using the stretch release conductive adhesive of FIGS. 1-5. As shown, the method 600 begins at step 602, which involves receiving a flexible circuit. Step 604 involves securing the flexible circuit or component to a conductive substrate using stretch release conductive adhesive. In some embodiments, the conductive substrate can be a housing. The component can include a wire, a cable, a battery, a fan, a speaker, a circuit board, or other electronic components. The surface can be made of any of a number of suitable materials, such as metal or plastic, and can include a portion of low friction material or a coating of low friction material.

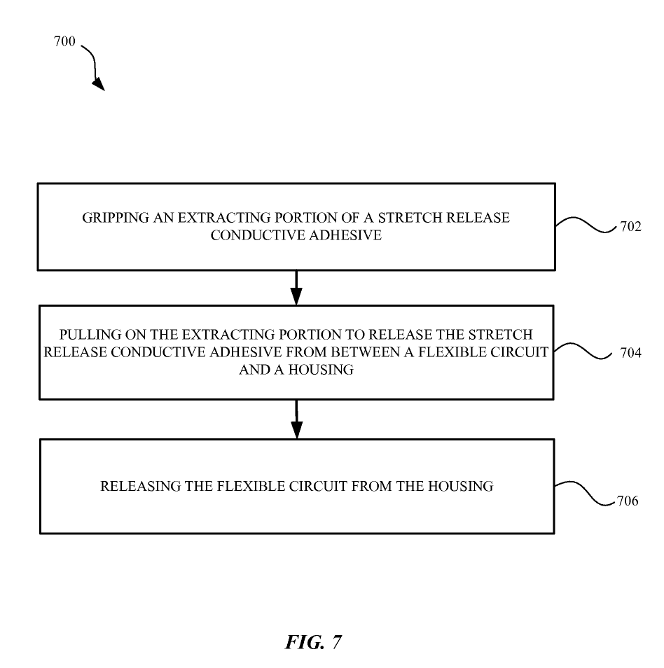

FIG. 7 illustrates a method 700 for removing a flexible circuit from a housing using stretch release conductive adhesive, according to one embodiment. In particular, the method 700 begins at step 702, which involves gripping an extracting portion of a stretch release conductive adhesive. Next, step 704 involves pulling on the extracting portion to release the stretch release conductive adhesive from between a flexible circuit and a housing. Finally, step 706 involves releasing the flexible circuit from the housing. This method 700 applies to FIGS. 1-5, and can therefore be used to remove stretch release conductive adhesive having multiple extracting portions, as illustrated in FIG. 5 and described herein.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A stretch release conductive adhesive, comprising:
a conductive compressible securing portion configured to secure a component to an interior surface of a housing of a computing device; and
an extracting portion coupled to the conductive compressible securing portion at a junction, wherein the extracting portion is arranged to receive an extracting force and transfer the extracting force to the conductive compressible securing portion by way of the junction.

2. The stretch release conductive adhesive of claim 1, wherein the component detaches from the housing as the extracting force is applied to the extracting portion, and the entire compressible securing portion is at a reduced thickness.

3. The stretch release conductive adhesive of claim 1, wherein the junction moves away from the component when the extracting force is applied to the extracting portion.

4. The stretch release conductive adhesive of claim 1, wherein the extracting portion includes a pull tab configured to be grasped and pulled to facilitate the extracting force.

5. The stretch release conductive adhesive of claim 1, further comprising multiple extracting portions.

6. The stretch release conductive adhesive of claim 1, further comprising conductive particles.

7. A method for securing a component in a housing, the method comprising:
securing the component to an interior surface of the housing using a stretch release conductive adhesive, wherein the stretch release conductive adhesive comprises a conductive compressible securing portion and an extracting portion coupled at a junction.

8. The method as recited in claim 7, wherein the housing is for a portable computing device.

9. The method as recited in claim 7, wherein the conductive compressible securing portion reduces thickness when applying an extracting force to the extracting portion.

10. The method as recited in claim 7, wherein the component is secured to an interior surface of the housing when the conductive compressible securing portion is at a securing thickness and is detached from the interior surface of the housing when the entire conductive compressible securing portion is at a reduced thickness.

11. The method as recited in claim 10, wherein the conductive compressible securing portion includes multiple different conductive particles.

12. A system configured to provide a conductive pathway between an electrical component and a conductive surface of a computing device, the system comprising:
a stretch release conductive adhesive removably attached to the electrical component and the conductive surface, wherein a conductive body of the stretch release conductive adhesive provides the conductive pathway between the electrical component and the conductive surface.

13. The system of claim 12, wherein the stretch release conductive adhesive comprises at least one material selected from a group comprising: silver, copper, gold, aluminum, calcium, tungsten, zinc, nickel, lithium, and iron.

14. The system of claim 12, wherein the stretch release conductive adhesive is configured to at partially reduce in thickness when receiving a lateral pulling force.

15. The system of claim 12, wherein the electrical component is a flexible circuit.

16. The system of claim 12, further comprising a plurality of electrical components electrically coupled to the conductive surface by the stretch release conductive adhesive.

17. The system of claim 12, wherein the stretch release conductive adhesive includes a graspable portion attached to the conductive body.

18. The system of claim 17, wherein the conductive body is configured to release from the conductive surface when the conductive body is at a reduced thickness.

19. The system of claim 12, wherein the stretch release conductive adhesive is capable of being re-used after being removed from the conductive surface.

20. The system of claim 12, wherein the stretch release conductive adhesive includes multiple extracting portions extending from the conductive body.
